(19) United States
(12) Patent Application Publication
(10) Pub. No.: US 2018/0274116 A1
(43) Pub. Date: Sep. 27, 2018

(54) PLATING APPARATUS AND METHOD FOR DETERMINING PLATING BATH CONFIGURATION

(71) Applicant: EBARA CORPORATION, TOKYO (JP)

(72) Inventors: Mitsuhiro SHAMOTO, Tokyo (JP); Masashi SHIMOYAMA, Tokyo (JP)

(21) Appl. No.: 15/925,490

(22) Filed: Mar. 19, 2018

(30) Foreign Application Priority Data
Mar. 22, 2017 (JP) 2017-055979

(51) Int. Cl. C25D 3/38; C25D 5/18; C25D 17/00; C25D 17/12; C25D 7/12; H05K 3/24; H01L 21/288; H01L 21/768; C25D 21/10; C25D 21/08

(52) U.S. Cl. CPC C25D 3/38; C25D 5/18; C25D 17/001; C25D 17/12; C25D 7/123; C25D 21/08; H01L 21/2885; H01L 21/76873; H01L 21/76843; C25D 21/10; H05K 3/241

(57) ABSTRACT

There is provided a plating apparatus for plating a rectangular substrate using a substrate holder holding the rectangular substrate. The plating apparatus comprises a plating bath configured to store the substrate holder holding the rectangular substrate, and an anode disposed inside the plating bath so as to face the substrate holder. The substrate holder includes an electrical contact configured to feed two opposite sides of the rectangular substrate. The rectangular substrate and the anode are placed inside the plating bath so as to satisfy the relationship of 0.59×L1−43.5 mm≤D1≤0.58×L1−19.8 mm, where L1 is the shortest distance between a substrate center of the rectangular substrate and the electrical contact, and D1 is the distance between the rectangular substrate and the anode.

### CROSS-REFERENCE TO RELATED APPLICATION

This application is based upon and claims benefit of priority from Japanese Patent Application No. 2017-055979 filed on Mar. 22, 2017, the entire contents of which are incorporated herein by reference.

### TECHNICAL FIELD

The present invention relates to a plating apparatus and a method for determining a plating bath configuration.

### BACKGROUND ART

Wirings, bumps (protruding electrodes), and the like have conventionally been formed on a surface of a substrate such as a semiconductor wafer or a printed circuit board. There has been known an electrolytic plating method as a method of forming such wirings and bumps.

In a plating apparatus for use in the electrolytic plating method, plating is normally performed on a circular substrate of a wafer or the like, for example, having a diameter of 300 mm. However, recent years have seen an increased demand for not only such conventional circular substrates but also rectangular substrates as cost-effective substrates in the semiconductor market. Thus, much attention has been paid to a method of performing cleaning, polishing, plating, and the like on the rectangular substrates.

The plating apparatus includes a plating bath. The plating bath includes therein, for example, a substrate holder holding a substrate, an anode holder holding an anode, a regulation plate (shielding plate), and the like. In such a plating apparatus, it is known that the distance between electrodes (inter-electrode distance) from the substrate to the anode affects the uniformity of the thickness of a film formed on the substrate. In light of this, there has been known a plating apparatus adjusting the inter-electrode distance (for example, see PTL 1, PTL 2, and the like). In addition, in the plating apparatus, not only the inter-electrode distance but also the opening shape and the installation position of the regulation plate as well as the opening shape of an anode mask of the anode holder and the like affect the uniformity of the thickness of a film formed on the substrate.

### CITATION LIST

### Patent Literature

PTL 1: Japanese Patent Laid-Open No. S63-270488
PTL 2: Japanese Patent Laid-Open No. 2002-226993

### SUMMARY OF INVENTION

### Technical Problem

The optimal inter-electrode distance in the plating apparatus depends on the size of the substrate. Conventionally, an appropriate inter-electrode distance is determined for each size of substrate by the rule of thumb and the determined distance is fine-tuned to approximate the optimal inter-electrode distance. However, it takes time to fine-tune the inter-electrode distance depending on the skill of the operator and the method cannot always find the optimal inter-electrode distance.

In addition, the circular substrates such as wafers have size standards such as mainly 150 mm, 200 mm, and 300 mm, and thus an appropriate inter-electrode distance can be relatively easily determined by the rule of thumb. However, the rectangular substrates currently do not have specific size standards and various sizes are available. Therefore, it is more difficult to determine an inter-electrode distance suitable for various sizes of rectangular substrates by the rule of thumb than that for specific sizes of circular substrates. In addition, since the inter-electrode distance affects the film thickness of the entire substrate, a shift of the inter-electrode distance makes it difficult to achieve in-plane uniformity of sufficient film thickness by adjusting the anode mask for adjusting the electric field or the opening size of the regulation plate.

As a result of intensive studies, the present inventors have found that there is a predetermined relationship between a distance from the center of a rectangular substrate to a contact point and an appropriate inter-electrode distance when feeding two opposite sides of the rectangular substrate. In view of the above problem, the present invention has been made, and an object of the present invention is to easily obtain an appropriate inter-electrode distance according to a rectangular substrate.

### Solution to Problem

An aspect of the present invention provides a plating apparatus for plating a rectangular substrate using a substrate holder holding the rectangular substrate. The plating apparatus comprises a plating bath configured to store the substrate holder holding the rectangular substrate, and an anode disposed inside the plating bath so as to face the substrate holder. The substrate holder includes an electrical contact configured to feed two opposite sides of the rectangular substrate. The rectangular substrate and the anode are placed inside the plating bath so as to satisfy the relationship of 0.59×L1−43.5 mm≤D1≤0.58×L1−19.8 mm, where L1 is the shortest distance between a substrate center of the rectangular substrate and the electrical contact, and D1 is the distance between the rectangular substrate and the anode.

An another aspect of the present invention provides a method for determining a configuration of a plating bath, wherein the plating bath stores a substrate holder holding a rectangular substrate, an anode holder holding an anode and including an anode mask shielding a part of the anode, and a regulation plate disposed between the substrate holder and the anode holder, the method determining each numerical value of an opening shape of the anode mask, an opening shape of a cylindrical portion of the regulation plate, a distance between the rectangular substrate and the anode, a distance between the rectangular substrate and the cylindrical portion of the regulation plate, and a length of the cylindrical portion of the regulation plate. The method comprises a first step of determining a numerical value of the opening shape of the anode mask having minimal variation in film thickness distribution of the rectangular substrate in a state where each of the numerical values other than the opening shape of the anode mask is set to a predetermined value; a second step of determining a numerical value of the opening shape of the cylindrical portion of the regulation plate having minimal variation in film thickness distribution of the rectangular substrate in a state where each of the numerical values other than the opening shape of the anode mask and the opening shape of the cylindrical portion of the regulation plate is set to a predetermined value and the opening shape of the anode mask is set to a value determined in the first step; a third step of determining a numerical value of the distance between the rectangular substrate and the anode having minimal variation in film thickness distribution of the rectangular substrate in a state where each of the numerical values of the distance between the rectangular substrate and the regulation plate and the length of the cylindrical portion of the regulation plate is set to a predetermined value, the opening shape of the anode mask is set to the value determined in the first step, and the opening shape of the cylindrical portion of the regulation plate is set to a value determined in the second step; a fourth step of determining a distance between the rectangular substrate and the regulation plate having minimal variation in film thickness distribution of the rectangular substrate in a state where a numerical value of the length of the cylindrical portion of the regulation plate is set to a predetermined value, the opening shape of the anode mask is set to the value determined in the first step, the opening shape of the cylindrical portion of the regulation plate is set to the value determined in the second step, the distance between the rectangular substrate and the anode is set to the value determined in the third step; and a fifth step thereof determining a length of the cylindrical portion of the regulation plate having minimal variation in film thickness distribution of the rectangular substrate in a state where the opening shape of the anode mask is set to the value determined in the first step, the opening shape of the cylindrical portion of the regulation plate is set to the value determined in the second step, the distance between the rectangular substrate and the anode is set to the value determined in the third step, and the distance between the rectangular substrate and the regulation plate is set to the value determined in the fourth step.

### BRIEF DESCRIPTION OF DRAWINGS

FIG. 1 is an overall layout view of a plating apparatus according to the present embodiment.

FIG. 2 is a schematic plan view of a substrate holder for use in the plating apparatus illustrated in FIG. 1.

FIG. 3 is a schematic plan view of a rectangular substrate held by the substrate holder illustrated in FIG. 2.

FIG. 4 is a schematic longitudinal sectional front view illustrating a plating bath and an overflow bath in a treatment section illustrated in FIG. 1.

FIG. 5 is a partial top view of the plating bath illustrated in FIG. 4.

FIG. 6 is a flow diagram illustrating an analysis process for determining an inter-electrode distance D1, a distance A1, a length B1, and a distance B′1.

FIG. 7 is a graph illustrating a relationship between the inter-electrode distance D1 obtained by the analysis process illustrated in FIG. 6 and the distance L1 from the center of the rectangular substrate to an electrical contact.

FIG. 8 is a graph illustrating a relationship between the distance A1 obtained by the analysis process illustrated in FIG. 6 and the distance L1 from the center of the rectangular substrate to the electrical contact.

FIG. 9 is a graph illustrating a relationship between the length B1 obtained by the analysis process illustrated in FIG. 6 and the distance L1 from the center of the rectangular substrate to the electrical contact.

### DESCRIPTION OF EMBODIMENTS

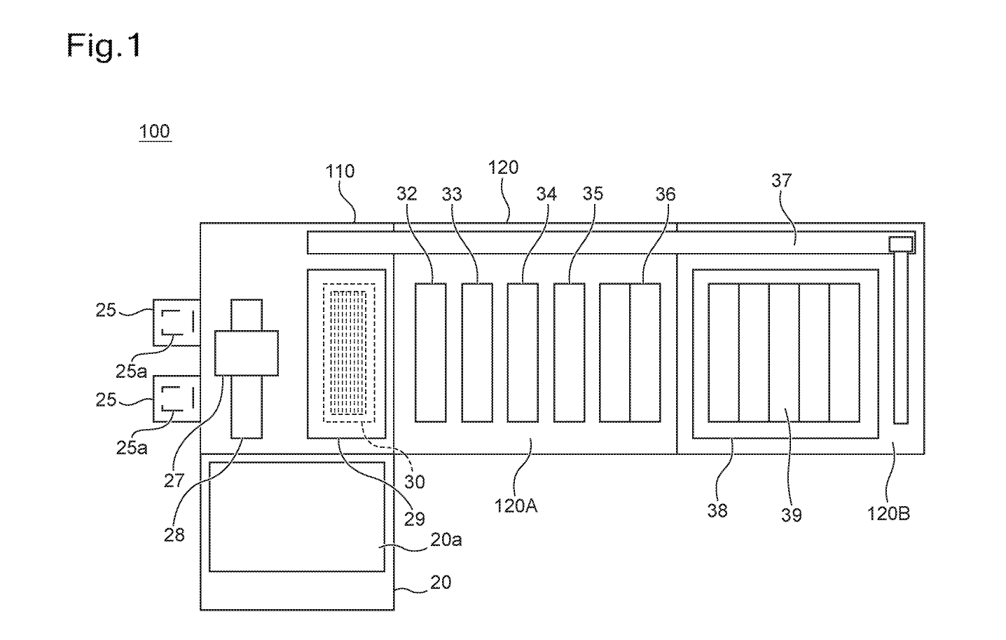

Hereinafter, embodiments of the present invention will be described with reference to the accompanying drawings. It should be noted that in the drawings described below, the same reference numerals or characters are assigned to the same or corresponding components and the description thereof is omitted. FIG. 1 is an overall layout view of a plating apparatus according to the present embodiment. As illustrated in FIG. 1, the plating apparatus 100 is roughly divided into a loading/unloading section 110 that loads a rectangular substrate into a substrate holder or unloads the rectangular substrate from the substrate holder, a treatment section 120 that treats the rectangular substrate, and a cleaning section 20. The treatment section 120 further includes a pre-treatment/post-treatment section 120A that performs pre-treatment and post-treatment on the rectangular substrate and a plating treatment section 120B that performs plating on the rectangular substrate. Each of the loading/unloading section 110, the treatment section 120, and the cleaning section 20 in the plating apparatus 100 is surrounded with a separate frame (housing).

The loading/unloading section 110 includes two cassette tables 25 and a substrate attaching/detaching mechanism 29. Each of the cassette tables 25 mounts a cassette 25a storing a rectangular substrate. The substrate attaching/detaching mechanism 29 is configured to attach and detach the rectangular substrate to and from an unillustrated substrate holder. In addition, a stocker 30 for storing the substrate holder is disposed near (for example, below) the substrate attaching/detaching mechanism 29. A substrate transport device 27 including transporting robots for transporting the rectangular substrate among these units 25, 29, and 30 is disposed at a center of these units. The substrate transport device 27 is configured to be able to travel by a traveling mechanism 28.

The cleaning section 20 includes a cleaning device 20a that cleans and dries the rectangular substrate after plating treatment. The substrate transport device 27 is configured to transport the rectangular substrate after the plating treatment to the cleaning device 20a and take out the cleaned and dried rectangular substrate from the cleaning device 20a.

The pre-treatment/post-treatment section 120A includes a pre-wet bath 32, a pre-soak bath 33, a pre-rinse bath 34, a blow bath 35, and a rinse bath 36. In the pre-wet bath 32, a rectangular substrate is immersed in pure water. In the pre-soak bath 33, an oxide film is removed by etching from the surface of a conductive layer such as a seed layer formed on the surface of the rectangular substrate. In the pre-rinse bath 34, the rectangular substrate after pre-soaking is cleaned with a cleaning fluid (pure water, etc.,) together with the substrate holder. In the blow bath 35, the rectangular substrate after cleaning is drained. In the rinse bath 36, the rectangular substrate after plating is cleaned with the cleaning fluid together with the substrate holder. The pre-wet bath 32, the pre-soak bath 33, the pre-rinse bath 34, the blow bath 35, and the rinse bath 36 are disposed in this order.

The plating treatment section 120B includes a plurality of plating baths 39 having an overflow bath 38. Each plating bath 39 stores a rectangular substrate therein. The rectangular substrate is immersed in a plating solution held inside the plating bath, and plating such as copper plating is performed on the surface of the rectangular substrate. Here, the type of the plating solution is not particularly limited, but various plating solutions may be used depending on the application.

The plating apparatus 100 includes a substrate holder transport device 37 which uses, for example, a linear motor system and is located on a side of each of these devices to transport the substrate holder together with the rectangular substrate to and from each of these devices. The substrate holder transport device 37 is configured to transport the substrate holder to and from the substrate attaching/detaching mechanism 29, the pre-wet bath 32, the pre-soak bath 33, the pre-rinse bath 34, the blow bath 35, the rinse bath 36, and the plating bath 39.

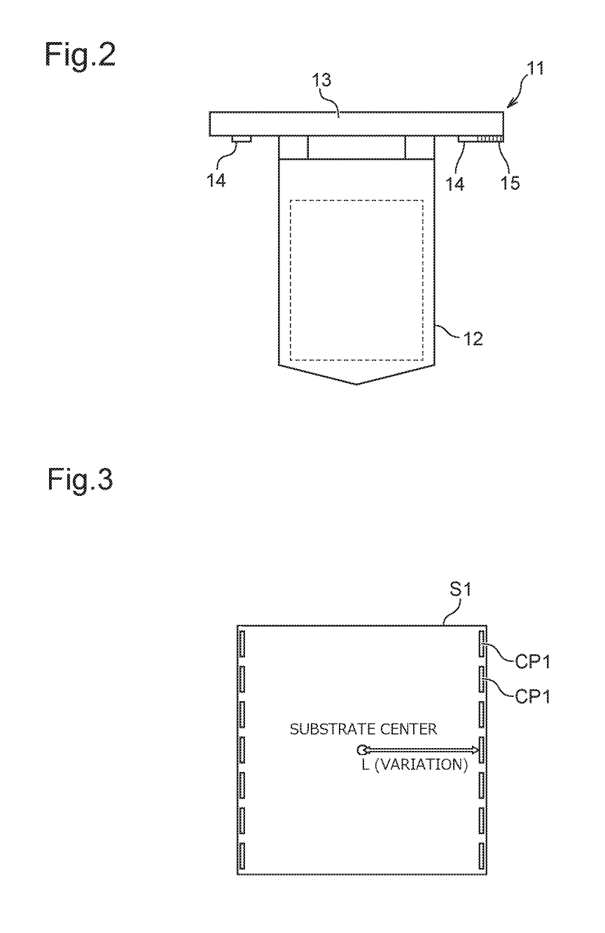

FIG. 2 is a schematic plan view of a substrate holder for use in the plating apparatus illustrated in FIG. 1. FIG. 3 is a schematic plan view of a rectangular substrate held by the substrate holder illustrated in FIG. 2. As illustrated in FIG. 2, the substrate holder 11 includes a substrate holder main body 12, for example, made of vinyl chloride and having a flat plate shape, and an arm portion 13 connected to the substrate holder main body 12. The arm portion 13 includes a pair of pedestals 14. When each of the pedestals 14 is installed on an upper surface of a peripheral wall of each treatment bath illustrated in FIG. 1, the substrate holder 11 is vertically suspended and supported. The arm portion 13 further includes a connector portion 15 configured to be in contact with an electrical contact disposed in the plating bath 39 when the pedestal 14 is installed on the upper surface of the peripheral wall of the plating bath 39. As a result, the substrate holder 11 is electrically connected to an external power source to apply voltage and current to the rectangular substrate held by the substrate holder 11.

The substrate holder 11 holds rectangular substrate S1 so as to expose a surface thereof to be plated as illustrated in FIG. 3. The substrate holder 11 includes unillustrated electrical contacts in contact with the surface of the rectangular substrate S1. When the substrate holder 11 holds the rectangular substrate S1, the electrical contacts are configured to be in contact with contact positions CP1 disposed along the two opposite sides of the rectangular substrate S1 as illustrated in FIG. 3. Note that the shape of the rectangular substrate is square or rectangular. In the case of the rectangular substrate of a rectangular shape, the electrical contacts are configured to be in contact with the two opposite long or short sides of the rectangular substrate.

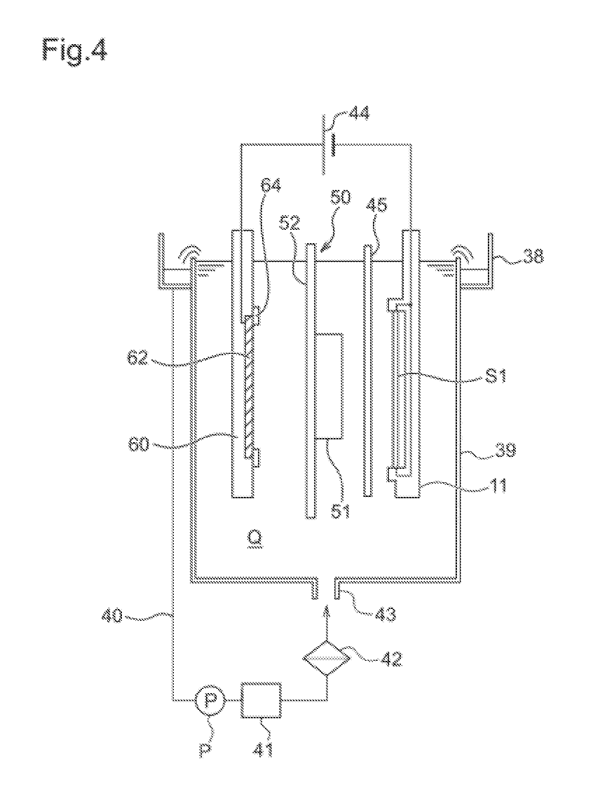

FIG. 4 is a schematic longitudinal sectional front view of the plating bath 39 and the overflow bath 38 in the treatment section 120B illustrated in FIG. 1. As illustrated in FIG. 4, the plating bath 39 hold a plating solution Q therein. The overflow bath 38 is disposed on an outer periphery of the plating bath 39 so as to receive the plating solution Q overflowing from an edge of the plating bath 39. An end of the plating solution supply path 40 including a pump P is connected to a bottom portion of the overflow bath 38. The other end of the plating solution supply path 40 is connected to the plating solution supply port 43 disposed on the bottom portion of the plating bath 39. Then, as the pump P is driven, the plating solution Q accumulated in the overflow bath 38 is returned into the plating bath 39. The plating solution supply path 40 on a downstream side of the pump P further includes a constant temperature unit 41 for adjusting the temperature of the plating solution Q and a filter 42 for removing foreign matter from the plating solution.

The plating bath 39 stores the substrate holder 11 holding the rectangular substrate S1. The substrate holder 11 is placed in the plating bath 39 such that the rectangular substrate S1 is vertically immersed in the plating solution Q. The 39 further stores an anode holder 60 holding an anode 62 that is placed at a position facing the rectangular substrate S1 in the plating bath 39. As the anode 62, for example, phosphorus-containing copper may be used. An anode mask 64 for shielding a part of the anode 62 is disposed on a front surface side (side facing the rectangular substrate S1) of the anode holder 60. The anode mask 64 includes an opening for passing electric force lines between the anode 62 and the rectangular substrate S1. The rectangular substrate S1 is electrically connected to the anode 62 via a plating power supply 44. When a current is supplied between the rectangular substrate S1 and the anode 62, a plating film (copper film) is formed on the surface of the rectangular substrate S1.

A paddle 45 reciprocating parallel to the surface of the rectangular substrate S1 and agitating the plating solution Q is placed between the rectangular substrate S1 and the anode 62. Sufficient copper ions can be uniformly supplied to the surface of the rectangular substrate S1 by agitating the plating solution Q by the paddle 45. In addition, a regulation plate 50 made of dielectric materials for providing a more uniform potential distribution over the entire surface of the rectangular substrate S1 is placed between the paddle 45 and the anode 62. The regulation plate 50 includes a flat plate-shaped main body portion 52 and a cylindrical portion 51 forming an opening for passing electric force lines.

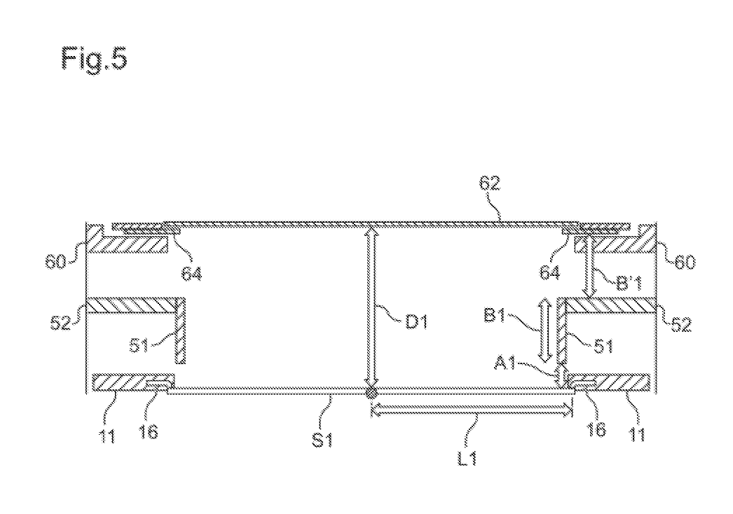

FIG. 5 is a partial top view of the plating bath 39 illustrated in FIG. 4. In FIG. 5, the paddle 45 is omitted. As illustrated in FIG. 5, the rectangular substrate S1 is disposed to face the anode 62 with a distance D1 therebetween. In other words, the plating bath 39 has an inter-electrode distance D1. The cylindrical portion 51 of the regulation plate 50 has a length B1. An end surface of the cylindrical portion 51 of the regulation plate 50 is separated from the rectangular substrate S1 by a distance A1. The other end surface of the cylindrical portion 51 of the regulation plate 50 is separated from the anode mask 64 by a distance B′1. The electrical contact 16 of the substrate holder 11 is in contact with a position separated from the center of the rectangular substrate S1 by a distance L1.

As described above, when plating is performed on the rectangular substrate S1 in the plating bath 39, the inter-electrode distance D1 affects the uniformity of the thickness of a film formed on the rectangular substrate S1. Similarly, an appropriate distance A1 between the cylindrical portion 51 and the rectangular substrate S1, the length B1 of the cylindrical portion 51, and the distance B′1 between the cylindrical portion 51 and the anode mask 64 also affect the uniformity of the thickness of the film formed on the rectangular substrate S1. Accordingly, in order to obtain the in-plane uniformity in good film thickness, at least one of the appropriate inter-electrode distance D1, the distance A1, the length B1, and the distance B′1 needs to be determined. As a result of intensive studies of feeding two opposite sides of the rectangular substrate S1 as illustrated in FIG. 5, the present inventors have found that there is a predetermined relationship between the distance L1 from the center of the rectangular substrate S1 to the electrical contact 16 and the appropriate inter-electrode distance D1. Similarly, the present inventors have found that there is a predetermined relationship between the distance L1 from the center of the rectangular substrate S1 to the electrical contact 16 and the appropriate distance A1 between the cylindrical portion 51 and the rectangular substrate S1 as well as the distance L1 from the center of the rectangular substrate S1 to the electrical contact 16 and the length B1 of the cylindrical portion 51.

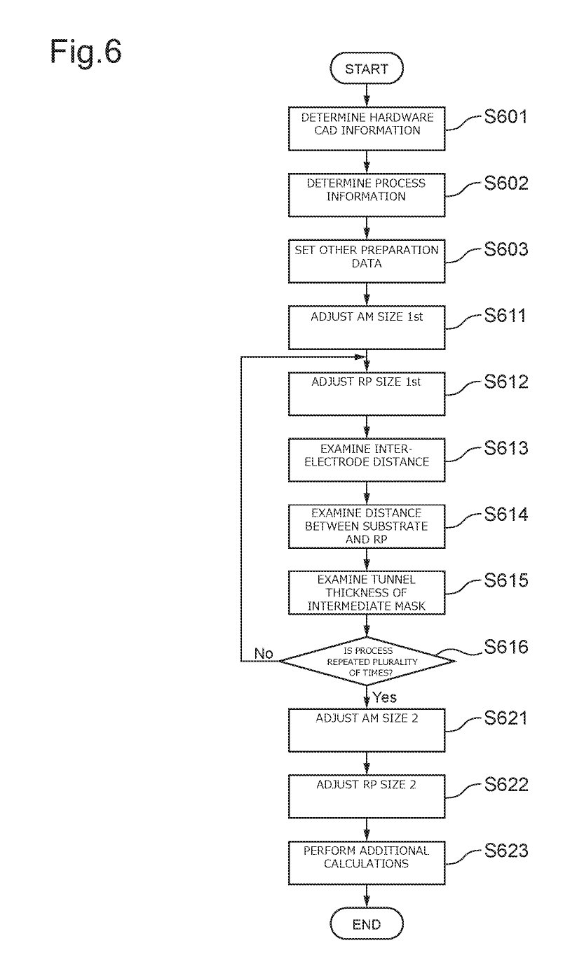

FIG. 6 is a flow diagram illustrating an analysis process for determining the inter-electrode distance D1, the distance A1, the length B1, and the distance B′1. The analysis process illustrated in FIG. 6 is roughly divided into pre-analysis preparation steps (step S601 to step S603), plating bath configuration determination steps (step S611 to step S616), and in-plane uniformity optimization steps (step S621 to step S623). This analysis process is performed using general analysis software.

In the pre-analysis preparation steps, first, hardware computer-aided design (CAD) information is determined (step S601) before the inter-electrode distance D1, the distance A1, the length B1, and the distance B′1 are determined. Specifically, information such as specifications of the rectangular substrate S1, the substrate holder 11, the anode holder 60, the plating bath 39, and the electrical contact 16 is set to the analysis software. Then, the process information is determined (step S602). Specifically, the plating conditions such as the plating solution, voltage values, and current values are set to the analysis software. Then, data such as preliminary experiment data, model data, and boundary conditions is set to the analysis software as needed (step S603).

Then, in the plating bath configuration determination steps, the opening shape of the anode mask is adjusted (step S611). Specifically, each of the predetermined values is set as each of the numerical values of the opening shape of the cylindrical portion 51 of the regulation plate 50, the inter-electrode distance D1, the distance A1 between the rectangular substrate S1 and the cylindrical portion 51 of the regulation plate 50, and the length B1 of the cylindrical portion 51. In this condition, the film thickness distribution of the rectangular substrate S1 is calculated, for example, by slightly shifting the numerical value within a range of numerical values expected to include the optimal value of the opening shape of the cylindrical portion 51. Within the range, the numerical value of the opening shape of the anode mask 64 having minimal variation in film thickness distribution of the rectangular substrate S1 is determined. Note that the predetermined values herein are appropriately determined by the rule of thumb. Note also that the opening shape of the anode mask 64 according to the present embodiment refers to the horizontal and vertical length of the quadrangular opening corresponding to the shape of the rectangular substrate S1. As the variation in film thickness distribution according to the present embodiment, for example, a value of 3σ may be adopted.

The opening shape of the cylindrical portion 51 of the regulation plate 50 is adjusted (step S612). Specifically, each of the predetermined values is set as each of the numerical values of the inter-electrode distance D1, the distance A1 between the rectangular substrate S1 and the cylindrical portion 51 of the regulation plate 50, and the length B1 of the cylindrical portion 51, and the numerical value determined in step S611 is set as the opening shape of the anode mask 64. In this condition, the film thickness distribution of the rectangular substrate S1 is calculated, for example, by slightly shifting the numerical value within a range of numerical values expected to include the optimal value of the opening shape of the cylindrical portion 51. Within the range, the numerical value of the opening shape of the cylindrical portion 51 having minimal variation in film thickness distribution of the rectangular substrate S1 is determined. Note that the predetermined values herein are appropriately determined by the rule of thumb. Note also that the opening shape of the cylindrical portion 51 according to the present embodiment refers to the horizontal and vertical length of the quadrangular opening corresponding to the shape of the rectangular substrate S1.

The inter-electrode distance D1 is examined (step S613). Specifically, each of the predetermined values is set as each of the numerical values of the distance A1 between the rectangular substrate S1 and the cylindrical portion 51 of the regulation plate 50, and the length B1 of the cylindrical portion 51, the numerical value determined in step S611 is set as the opening shape of the anode mask 64, and the numerical value determined in step S612 is set as the opening shape of the cylindrical portion 51. In this condition, the film thickness distribution of the rectangular substrate S1 is calculated, for example, by shifting the value of the inter-electrode distance D1 by 5 mm within a range of numerical values expected to include the optimal value. Within the range, the numerical value of the inter-electrode distance D1 having minimal variation in film thickness distribution of the rectangular substrate S1 is determined. Note that the predetermined values herein are appropriately determined by the rule of thumb.

The distance A1 between the cylindrical portion 51 and the rectangular substrate S1 is examined (step S614). Specifically, the predetermined value is set as the length B1 of the cylindrical portion 51, the numerical value determined in step S611 is set as the opening shape of the anode mask 64, the numerical value determined in step S612 is set as the opening shape of the cylindrical portion 51, and the numerical value determined in step S613 is set as the inter-electrode distance D1. In this condition, the film thickness distribution of the rectangular substrate S1 is calculated, for example, by slightly shifting the numerical value of the distance A1 within a range of numerical values expected to include the optimal value. Within the range, the numerical value of the distance A1 between the cylindrical portion 51 and the rectangular substrate S1 having minimal variation in film thickness distribution of the rectangular substrate S1 is determined. Note that the predetermined values herein are appropriately determined by the rule of thumb.

The length B1 of the cylindrical portion 51 is examined (step S615). Specifically, the numerical value determined in step S611 is set as the opening shape of the anode mask 64, the numerical value determined in step S612 is set as the opening shape of the cylindrical portion 51, the numerical value determined in step S613 is set as the inter-electrode distance D1, and the numerical value determined in step S614 is set as the distance A1 between the cylindrical portion 51 and the rectangular substrate S1. In this condition, the film thickness distribution of the rectangular substrate S1 is calculated, for example, by slightly shifting the numerical value of the length B1 within a range of numerical values expected to include the optimal value. Within the range, the numerical value of the length B1 of the cylindrical portion 51 having minimal variation in film thickness distribution of the rectangular substrate S1 is determined. Note that the predetermined values herein are appropriately determined by the rule of thumb.

Once the inter-electrode distance D1, the distance A1, and the length B1 are determined, the distance B′1 is automatically determined. Accordingly, the analysis of the distance B′1 need not be performed. Thus, each numerical value is determined in step S611 to step S615. However, if the above predetermined value set during examination of each numerical value is not appropriate, each numerical value may not be determined to be appropriate. For this reason, in the present embodiment, the process from step S612 to step S615 may be repeated a plurality of times (step S616).

In the second and subsequent step S611, each of the numerical values determined in the already executed step S613 to step S615 is set as the opening shape of the cylindrical portion 51 of the regulation plate 50, the inter-electrode distance D1, the distance A1 between the rectangular substrate S1 and the cylindrical portion 51 of the regulation plate 50, and the length B1 of the cylindrical portion 51. In this condition, the numerical value of the opening shape of the anode mask 64 having minimal variation in film thickness distribution of the rectangular substrate S1 is determined again (step S611). Specifically, in the second and subsequent step S612, the numerical value of the opening shape of the anode mask 64 having minimal variation in film thickness distribution of the rectangular substrate S1 is determined not by the predetermined value determined by the rule of thumb, but by the numerical value determined by the already executed analysis.

Similarly, in the second and subsequent step S612, each of the numerical values determined in the already executed step S611, step S613 to step S615 is set as the opening shape of the anode mask 64, the inter-electrode distance D1, the distance A1 between the rectangular substrate S1 and the cylindrical portion 51 of the regulation plate 50, and the length B1 of the cylindrical portion 51. In this condition, the numerical value of the opening shape of the cylindrical portion 51 having minimal variation in film thickness distribution of the rectangular substrate S1 is determined again (step S612).

In the second and subsequent step S613, each of the numerical values determined in the already executed step S611, step S612, step S614, and step S615 is set as the opening shape of the anode mask 64, the opening shape of the cylindrical portion 51 of the regulation plate 50, the distance A1 between the rectangular substrate S1 and the cylindrical portion 51 of the regulation plate 50, and the length B1 of the cylindrical portion 51. In this condition, the numerical value of the inter-electrode distance D1 having minimal variation in film thickness distribution of the rectangular substrate S1 is determined again.

In the second and subsequent step S614, each of the numerical values determined in the already executed step S611, step S612, step S614, and step S615 is set as the opening shape of the anode mask 64, the opening shape of the cylindrical portion 51 of the regulation plate 50, the inter-electrode distance D1, and the length B1 of the cylindrical portion 51. In this condition, the numerical value of the distance A1 between the rectangular substrate S1 and the cylindrical portion 51 of the regulation plate 50 having minimal variation in film thickness distribution of the rectangular substrate S1 is determined again.

In the second and subsequent step S615, each of the numerical values determined in the already executed step S611 to step S614 is set as the opening shape of the anode mask 64, the opening shape of the cylindrical portion 51 of the regulation plate 50, the inter-electrode distance D1, and the distance A1 between the rectangular substrate S1 and the cylindrical portion 51 of the regulation plate 50. In this condition, the numerical value of the distance A1 between the rectangular substrate S1 and the cylindrical portion 51 of the regulation plate 50 having minimal variation in film thickness distribution of the rectangular substrate S1 is determined again.

As described above, the process from step S611 to step S615 is repeated a plurality of times and thereby each numerical value can be determined not by using the predetermined values determined by the rule of thumb, but by mutually using each of the numerical values determined by the analysis. Thus, each numerical value can be determined to further reduce variation in the film thickness distribution of the rectangular substrate S1. Note that if the predetermined value determined by the rule of thumb is appropriate, the appropriate predetermined value can be used to determine each numerical value having minimal variation in film thickness distribution of the rectangular substrate S1 without repeating the process from step S611 to step S615 a plurality of times.

Then, in the in-plane uniformity optimization step, the opening shape of the anode mask 64 is adjusted (step S621) and the opening shape of the cylindrical portion 51 of the regulation plate 50 is adjusted (step S622). In the plating bath configuration determination steps from step S611 to step S616, the opening shape of the anode mask 64 and the opening shape of the cylindrical portion 51 of the regulation plate 50 have already been determined. However, these opening shapes determined in the plating bath configuration determination steps are determined mainly as information required to determine the inter-electrode distance D1, the distance A1, and the length B1. Thus, step S621 and step S622 are executed for confirmation and final adjustments of these opening shapes are performed. Finally, additional calculations are performed as needed (step S623).

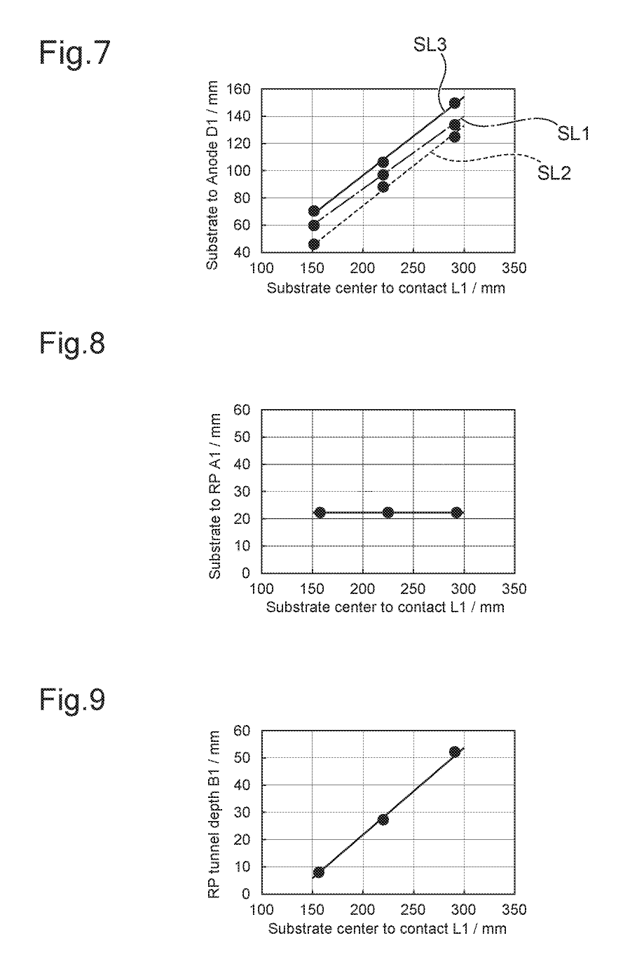

The inter-electrode distance D1, the distance A1, the length B1, and the distance B′1 obtained by the above described analysis process have a predetermined relationship with the distance L1 from the center of the rectangular substrate S1 to the electrical contact 16. FIG. 7 is a graph illustrating a relationship between the inter-electrode distance D1 obtained by the analysis process illustrated in FIG. 6 and the distance L1 from the center of the rectangular substrate S1 to the electrical contact 16. FIG. 8 is a graph illustrating a relationship between the distance A1 obtained by the analysis process illustrated in FIG. 6 and the distance L1 from the center of the rectangular substrate S1 to the electrical contact 16. FIG. 9 is a graph illustrating a relationship between the length B1 obtained by the analysis process illustrated in FIG. 6 and the distance L1 from the center of the rectangular substrate S1 to the electrical contact 16.

FIG. 7 illustrates a straight line SL1 connecting plots indicating the inter-electrode distance D1 where 3σ representing a variation in film thickness distribution of the rectangular substrate S1 is minimum when the distance L1 from the center of the rectangular substrate S1 to the electrical contact 16 is 150 mm, 220 mm, and 280 mm. FIG. 7 also illustrates a straight line SL2 connecting plots indicating the inter-electrode distance D1 where 3σ is a minimum +1% when the distance L1 from the center of the rectangular substrate S1 to the electrical contact 16 is 150 mm, 220 mm, and 280 mm with a plot point (D1) on the straight line SL1 as a reference in the direction of reducing the inter-electrode distance. Similarly, FIG. 7 also illustrates a straight line SL3 connecting plots indicating the inter-electrode distance D1 where 3σ is a minimum +1% when the distance L1 from the center of the rectangular substrate S1 to the electrical contact 16 is 150 mm, 220 mm, and 280 mm with a plot point (D1) on the straight line SL1 as a reference in the direction of increasing the inter-electrode distance.

As illustrated in FIG. 7, there is a proportional relationship between the inter-electrode distance D1 when 3σ is minimum and the distance L1 from the center of the rectangular substrate S1 to the electrical contact 16. Specifically, the straight line SL1 has a relationship of D1=0.53L1−18.7 mm. In addition, the straight line SL2 has a relationship of D1=0.59L1−43.5 mm, and the straight line SL3 has a relationship of D1=0.58L−19.8 mm. Since the distance L1 from the center of the rectangular substrate S1 to the electrical contact 16 is determined by the structure of the substrate holder 11 and the size of the rectangular substrate S1, the distance L1 is generally a predetermined value. Therefore, assuming that the relational expression illustrated in FIG. 7 is obtained, if the distance L1 from the center of the rectangular substrate S1 to the electrical contact 16 is given, the optimal inter-electrode distance D1 can be easily obtained.

Note that if 3σ representing a variation in film thickness distribution of the rectangular substrate S1 is within a minimum +1%, the rectangular substrate S1 generally has sufficient in-plane uniformity as a product. Therefore, when the distance L1 is given, a value in the range of 0.59L1−43.5 mm≤D1≤0.58L−19.8 mm is preferably used as the inter-electrode distance D1. Accordingly, once the distance L1 is given, an appropriate range of inter-electrode distance D1 can be easily obtained.

FIG. 8 illustrates a straight line connecting plots indicating the distance A1 where 3σ representing a variation in film thickness distribution of the rectangular substrate S1 is minimum when the distance L1 from the center of the rectangular substrate S1 to the electrical contact 16 is 160 mm, 225 mm, and 280 mm. As illustrated in FIG. 8, there is a certain relationship between the distance A1 when 3σ is minimum and the distance L1 from the center of the rectangular substrate S1 to the electrical contact 16. Specifically, as illustrated in FIG. 8, when the distance A1 is 20.8 mm, 3σ is minimum regardless the value of the distance L1 from the center of the rectangular substrate S1 to the electrical contact 16. Therefore, assuming that the relational expression illustrated in FIG. 8 is obtained, if the distance L1 from the center of the rectangular substrate S1 to the electrical contact 16 is given, the optimal distance A1 can be easily obtained.

FIG. 9 illustrates a straight line connecting plots indicating the length B1 where 3σ representing a variation in film thickness distribution of the rectangular substrate S1 is minimum when the distance L1 from the center of the rectangular substrate S1 to the electrical contact 16 is 160 mm, 220 mm, and 280 mm. As illustrated in FIG. 9, there is a certain relationship between the length B1 when 3σ is minimum and the distance L1 from the center of the rectangular substrate S1 to the electrical contact 16. Specifically, as illustrated in FIG. 9, 3σ is minimum when the length B1 and the distance L1 from the center of the rectangular substrate S1 to the electrical contact 16 satisfy the relationship of B1=0.33L−43.3 mm. Therefore, assuming that the relational expression illustrated in FIG. 9 is obtained, if the distance L1 from the center of the rectangular substrate S1 to the electrical contact 16 is given, the optimal length B1 can be easily obtained.

In the present embodiment, the analysis process illustrated in FIG. 6 produces graphs each indicating a relationship between the inter-electrode distance D1, the distance A1, and the length B1, and the distance L1 from the center of the rectangular substrate S1 to the electrical contact 16 illustrated in FIGS. 7 to 9. Then, the inter-electrode distance D1, the distance A1, the length B1, the length B′1, and the distance L1 from the center of the rectangular substrate S1 to the electrical contact 16 of the plating bath 39 illustrated in FIGS. 4 and 5 are set to satisfy the relationships illustrated in FIGS. 7 to 9. Thus, the plating bath 39 can be easily configured to minimize the film thickness distribution of the rectangular substrate S1.

Hereinbefore, the embodiments of the present invention have been described. The above described embodiments of the invention are provided to facilitate the understanding of the present invention and are not intended to limit the present invention. It is apparent that the present invention may be changed or improved without departing from the spirit of the invention and such equivalents are included in the present invention. Further, the individual components described in the claims and the specification may be appropriately combined or omitted within a range in which at least some of the above described problems can be solved or within a range in which at least some of the effects can be exhibited.

Hereinafter, some of the aspects disclosed herein will be described. A first aspect provides a plating apparatus for plating a rectangular substrate using a substrate holder holding the rectangular substrate. The plating apparatus comprises a plating bath configured to store the substrate holder holding the rectangular substrate, and an anode disposed inside the plating bath so as to face the substrate holder. The substrate holder includes an electrical contact configured to feed two opposite sides of the rectangular substrate. The rectangular substrate and the anode are placed inside the plating bath so as to satisfy the relationship of 0.59×L1−43.5 mm≤D1≤0.58×L1−19.8 mm, where L1 is the shortest distance between a substrate center of the rectangular substrate and the electrical contact, and D1 is the distance between the rectangular substrate and the anode.

The first aspect can minimize the film thickness distribution of a plating film formed on the rectangular substrate by setting L1 and D1 so as to satisfy the above relationship. In other words, if one of L1 and D1 is given, the other of L1 and D1 can be easily set to minimize the film thickness distribution of a plating film formed on the rectangular substrate based on the above relationship.

According to a second aspect, the plating apparatus of the first aspect comprises a regulation plate disposed between the substrate holder and the anode, wherein the regulation plate includes a cylindrical portion forming an opening for passing electric force lines, and the cylindrical portion has a length satisfying a relationship of B1=0.33×L1−43.3 mm, where B1 denotes the length of the cylindrical portion.

The second aspect can minimize the film thickness distribution of a plating film formed on the rectangular substrate by setting L1 and B1 so as to satisfy the above relationship. In other words, if one of L1 and B1 is given, the other of L1 and B1 can be easily set to minimize the film thickness distribution of a plating film formed on the rectangular substrate based on the above relationship.

According to a third aspect, the plating apparatus of the first aspect or the second aspect comprises a regulation plate disposed between the substrate holder and the anode, wherein the regulation plate includes a cylindrical portion forming an opening for passing electric force lines, and satisfies a relation of A1=20.8 mm, where A1 denotes the distance between the surface of the rectangular substrate stored in the plating apparatus and the cylindrical portion.

The third aspect can minimize the film thickness distribution of a plating film formed on the rectangular substrate by setting L1 and A1 so as to satisfy the above relationship. In other words, if one of L1 and A1 is given, the other of L1 and A1 can be easily set to minimize the film thickness distribution of a plating film formed on the rectangular substrate based on the above relationship.

A fourth aspect provides a method for determining a configuration of a plating bath, wherein the plating bath stores a substrate holder holding a rectangular substrate, an anode holder holding an anode and including an anode mask shielding a part of the anode, and a regulation plate disposed between the substrate holder and the anode holder, the method determining each numerical value of an opening shape of the anode mask, an opening shape of a cylindrical portion of the regulation plate, a distance between the rectangular substrate and the anode, a distance between the rectangular substrate and the cylindrical portion of the regulation plate, and a length of the cylindrical portion of the regulation plate. The method comprises a first step of determining a numerical value of the opening shape of the anode mask having minimal variation in film thickness distribution of the rectangular substrate in a state where each of the numerical values other than the opening shape of the anode mask is set to a predetermined value; a second step of determining a numerical value of the opening shape of the cylindrical portion of the regulation plate having minimal variation in film thickness distribution of the rectangular substrate in a state where each of the numerical values other than the opening shape of the anode mask and the opening shape of the cylindrical portion of the regulation plate is set to a predetermined value and the opening shape of the anode mask is set to the value determined in the first step; a third step of determining a numerical value of the distance between the rectangular substrate and the anode having minimal variation in film thickness distribution of the rectangular substrate in a state where each of the numerical values of the distance between the rectangular substrate and the regulation plate and the length of the cylindrical portion of the regulation plate is set to a predetermined value, the opening shape of the anode mask is set to the value determined in the first step, and the opening shape of the cylindrical portion of the regulation plate is set to the value determined in the second step; a fourth step of determining a distance between the rectangular substrate and the regulation plate having minimal variation in film thickness distribution of the rectangular substrate in a state where a numerical value of the length of the cylindrical portion of the regulation plate is set to a predetermined value, the opening shape of the anode mask is set to the value determined in the first step, the opening shape of the cylindrical portion of the regulation plate is set to the value determined in the second step, the distance between the rectangular substrate and the anode is set to the value determined in the third step; and a fifth step of determining a length of the cylindrical portion of the regulation plate having minimal variation in film thickness distribution of the rectangular substrate in a state where the opening shape of the anode mask is set to the value determined in the first step, the opening shape of the cylindrical portion of the regulation plate is set to the value determined in the second step, the distance between the rectangular substrate and the anode is set to the value determined in the third step, and the distance between the rectangular substrate and the regulation plate is set to the value determined in the fourth step.

The fourth aspect can determine the opening shape of the anode mask, the opening shape of the cylindrical portion of the regulation plate, the distance between the rectangular substrate and the anode, the distance between the rectangular substrate and the cylindrical portion of the regulation plate, and the length of the cylindrical portion of the regulation plate that can minimize the film thickness distribution of a plating film formed on the rectangular substrate.

According to a fifth aspect, the method of the fourth aspect further comprises: a sixth step of redetermining the opening shape of the anode mask having minimal variation in film thickness distribution of the rectangular substrate in a state where the opening shape of the cylindrical portion of the regulation plate is set to the value determined in the second step, the distance between the rectangular substrate and the anode is set to the value determined in the third step, the distance between the rectangular substrate and the regulation plate is set to the value determined in the fourth step, and the length of the cylindrical portion of the regulation plate is set to the value determined in the fifth step; a seventh step of redetermining the opening shape of the cylindrical portion of the regulation plate having minimal variation in film thickness distribution of the rectangular substrate in a state where the opening shape of the anode mask is set to the value determined in the sixth step, the distance between the rectangular substrate and the anode is set to the value determined in the third step, the distance between the rectangular substrate and the regulation plate is set to the value determined in the fourth step, and the length of the cylindrical portion of the regulation plate is set to the value determined in the fifth step; an eighth step of redetermining the distance between the rectangular substrate and the anode having minimal variation in film thickness distribution of the rectangular substrate in a state where the opening shape of the anode mask is set to the value determined in the sixth step, the opening shape of the cylindrical portion of the regulation plate is set to the value determined in the seventh step, the distance between the rectangular substrate and the regulation plate is set to the value determined in the fourth step, and the length of the cylindrical portion of the regulation plate is set to the value determined in the fifth step; a ninth step of redetermining the distance between the rectangular substrate and the regulation plate having minimal variation in film thickness distribution of the rectangular substrate in a state where the opening shape of the anode mask is set to the value determined in the sixth step, the opening shape of the cylindrical portion of the regulation plate is set to the value determined in the seventh step, the distance between the rectangular substrate and the anode is set to the value determined in the eighth step, the length of the cylindrical portion of the regulation plate is set to the value determined in the fifth step; and a tenth step of redetermining the length of the cylindrical portion of the regulation plate having minimal variation in film thickness distribution of the rectangular substrate in a state where the opening shape of the anode mask is set to the value determined in the sixth step, the opening shape of the cylindrical portion of the regulation plate is set to the value determined in the seventh step, the distance between the rectangular substrate and the anode is set to the value determined in the eighth step, and the distance between the rectangular substrate and the regulation plate is set to the value determined in the ninth step.

The fifth aspect can determine the opening shape of the anode mask, the opening shape of the cylindrical portion of the regulation plate, the distance between the rectangular substrate and the anode, the distance between the rectangular substrate and the cylindrical portion of the regulation plate, and the length of the cylindrical portion of the regulation plate that can further reduce the film thickness distribution of a plating film formed on the rectangular substrate.

According to a sixth aspect, the fourth aspect or the fifth aspect further comprises a step of adjusting the opening shape of the anode mask, and a step of adjusting the opening shape of the cylindrical portion of the regulation plate.

### REFERENCE SIGNS LIST

11 substrate holder
39 plating bath
50 regulation plate
51 cylindrical portion
60 anode holder
62 anode
64 anode mask
S1 rectangular substrate

What is claimed is:

1. A plating apparatus for plating a rectangular substrate using a substrate holder holding the rectangular substrate, the plating apparatus comprising:
a plating bath configured to store the substrate holder holding the rectangular substrate, and
an anode disposed inside the plating bath so as to face the substrate holder, wherein
the substrate holder includes an electrical contact configured to feed two opposite sides of the rectangular substrate, and
the rectangular substrate and the anode are placed inside the plating bath so as to satisfy the relationship of
0.59×L1−43.5 mm≤D1≤0.58×L1−19.8 mm, where
L1 is a distance between a substrate center of the rectangular substrate and the electrical contact, and D1 is a distance between the rectangular substrate and the anode.

2. The plating apparatus according to claim 1, further comprising
a regulation plate disposed between the substrate holder and the anode, wherein
the regulation plate includes a cylindrical portion forming an opening for passing electric force lines, and
the cylindrical portion has a length satisfying a relationship of
B1=0.33×L1−43.3 mm, where
B1 denotes the length of the cylindrical portion.

3. The plating apparatus according to claim 1, further comprising
a regulation plate disposed between the substrate holder and the anode, wherein
the regulation plate includes a cylindrical portion forming an opening for passing electric force lines, and
satisfies a relationship of
A1=20.8 mm, where
A1 denotes the distance between the surface of the rectangular substrate stored in the plating apparatus and the cylindrical portion.

4. A method for determining a configuration of a plating bath, wherein the plating bath stores a substrate holder holding a rectangular substrate, an anode holder holding an anode and including an anode mask shielding a part of the anode, and a regulation plate disposed between the substrate holder and the anode holder,
the method determining each numerical value of an opening shape of the anode mask, an opening shape of a cylindrical portion of the regulation plate, a distance between the rectangular substrate and the anode, a distance between the rectangular substrate and the cylindrical portion of the regulation plate, and a length of the cylindrical portion of the regulation plate, the method comprising:
a first step of determining a numerical value of the opening shape of the anode mask having minimal variation in film thickness distribution of the rectangular substrate in a state where each of the numerical values other than the opening shape of the anode mask is set to a predetermined value;
a second step of determining a numerical value of the opening shape of the cylindrical portion of the regulation plate having minimal variation in film thickness distribution of the rectangular substrate in a state where each of the numerical values other than the opening shape of the anode mask and the opening shape of the cylindrical portion of the regulation plate is set to a predetermined value and the opening shape of the anode mask is set to the value determined in the first step;
a third step of determining a numerical value of the distance between the rectangular substrate and the anode having minimal variation in film thickness distribution of the rectangular substrate in a state where each of the numerical values of the distance between the rectangular substrate and the regulation plate and the length of the cylindrical portion of the regulation plate is set to a predetermined value, the opening shape of the anode mask is set to the value determined in the first step, and the opening shape of the cylindrical portion of the regulation plate is set to the value determined in the second step;
a fourth step of determining a distance between the rectangular substrate and the regulation plate having minimal variation in film thickness distribution of the rectangular substrate in a state where a numerical value of the length of the cylindrical portion of the regulation plate is set to a predetermined value, the opening shape of the anode mask is set to the value determined in the first step, the opening shape of the cylindrical portion of the regulation plate is set to the value determined in the second step, the distance between the rectangular substrate and the anode is set to the value determined in the third step; and
a fifth step of determining a length of the cylindrical portion of the regulation plate having minimal variation in film thickness distribution of the rectangular substrate in a state where the opening shape of the anode mask is set to the value determined in the first step, the opening shape of the cylindrical portion of the regulation plate is set to the value determined in the second step, the distance between the rectangular substrate and the anode is set to the value determined in the third step, and the distance between the rectangular substrate and the regulation plate is set to the value determined in the fourth step.

5. The method according to claim 4, further comprising:
a sixth step of redetermining the opening shape of the anode mask having minimal variation in film thickness distribution of the rectangular substrate in a state where the opening shape of the cylindrical portion of the regulation plate is set to the value determined in the second step, the distance between the rectangular substrate and the anode is set to the value determined in the third step, the distance between the rectangular substrate and the regulation plate is set to the value determined in the fourth step, and the length of the cylindrical portion of the regulation plate is set to the value determined in the fifth step;
a seventh step of redetermining the opening shape of the cylindrical portion of the regulation plate having minimal variation in film thickness distribution of the rectangular substrate in a state where the opening shape of the anode mask is set to the value determined in the sixth step, the distance between the rectangular substrate and the anode is set to the value determined in the third step, the distance between the rectangular substrate and the regulation plate is set to the value determined in the fourth step, and the length of the cylindrical portion of the regulation plate is set to the value determined in the fifth step;
an eighth step of redetermining the distance between the rectangular substrate and the anode having minimal variation in film thickness distribution of the rectangular substrate in a state where the opening shape of the anode mask is set to the value determined in the sixth step, the opening shape of the cylindrical portion of the regulation plate is set to the value determined in the seventh step, the distance between the rectangular substrate and the regulation plate is set to the value determined in the fourth step, and the length of the cylindrical portion of the regulation plate is set to the value determined in the fifth step;
a ninth step of redetermining the distance between the rectangular substrate and the regulation plate having minimal variation in film thickness distribution of the rectangular substrate in a state where the opening shape of the anode mask is set to the value determined in the sixth step, the opening shape of the cylindrical portion of the regulation plate is set to the value determined in the seventh step, the distance between the rectangular substrate and the anode is set to the value determined in the eighth step, and the length of the cylindrical portion of the regulation plate is set to the value determined in the fifth step; and
a tenth step of redetermining the length of the cylindrical portion of the regulation plate having minimal variation in film thickness distribution of the rectangular substrate in a state where the opening shape of the anode mask is set to the value determined in the sixth step, the opening shape of the cylindrical portion of the regulation plate is set to the value determined in the seventh step, the distance between the rectangular substrate and the anode is set to the value determined in the eighth step, and the distance between the rectangular substrate and the regulation plate is set to the value determined in the ninth step.

6. The method according to claim 4, further comprising:
a step of adjusting the opening shape of the anode mask; and
a step of adjusting the opening shape of the cylindrical portion of the regulation plate.
